(19) United States
(12) Patent Application Publication
(10) Pub. No.: US 2008/0169150 A1
(43) Pub. Date: Jul. 17, 2008

(54) Reflection-type sound box

(76) Inventor: Tsung-Cheng Kuo, Taoyuan Hsien (TW)

Correspondence Address: TROXELL LAW OFFICE PLLC, Suite 1404, 5205 Leesburg Pike, Falls Church, VA, 22041, US

(21) Appl. No.: 11/652,667

(22) Filed: Jan. 12, 2007

(51) Int. Cl. H05K 5/02

(52) U.S. Cl. 181/155

(57) ABSTRACT

A reflection-type sound box comprises a box body and a loudspeaker. The box body comprises an upper shell, a lower shell for correspondingly coupling with the upper shell, and a sound chamber defined by the upper shell and the lower shell jointly. The sound chamber has a reflection duct extending inward from the upper shell and a sound cup extending inward from the lower shell. The sound cup is located to cover the outside of the reflection duct, and the sound cup and the reflection duct are spaced by a predetermined distance. The loudspeaker has an outward expanded opening and the loudspeaker is mounted in the box body for generating the sounds. The upper shell can be coupled with the lower shell easily by convex/concave engagement between the sound cup and the reflection duct. Accordingly, the reflection-type sound box has space-saving, small-noise, high-efficiency, and low-cost advantages.

### FIELD OF THE INVENTION

The present invention relates to an improved reflection-type sound box, and more particularly to a reflection-type sound box that has a sound cup and a reflection duct to engage the upper shell with the lower shell easily for providing space-saving, small-noise, high-efficiency, and low-cost advantages.

### BACKGROUND OF THE INVENTION

All of conventional reflection-type sound boxes have a box body, a vibration film for generating sounds, and a reflection hole on the box body. As a result, when the vibration film makes an action, the air inside the box body can be compressed to generate the back waves for increasing the volume of the low-frequency sounds for providing the sound box with better resonance effect. In addition, the reflection-type sound box has efficiency 2-3 dB higher than that of the close-type sound box. Accordingly, the low-frequency volume of the reflection-type sound box is more obvious than that of the close-type sound box.

However, the low frequency sounds are affected by the size of the box body and the size, position, and shape of the reflection hole. Accordingly, the design and difficulty degree of the reflection-type sound box are more complicated than that of the commonly seen close-type sound box.

Moreover, the conventional reflection-type sound box only has the reflection hole so it has a limited resonance effect. The whole efficiency and the tone color of the sound box are significantly affected if the reflection hole is poorly designed. As a result, there is a desire to develop a reflection-type sound box with space-saving, small-noise, high-efficiency, and low-cost advantages.

### SUMMARY OF THE INVENTION

In view of the above-mentioned conventional defects, a major object of the present invention is to provide a reflection-type sound box with space-saving, small-noise, high-efficiency, and low-cost advantages.

In order to achieve the above-mentioned object, a reflection-type sound box is comprised of a box body and a loudspeaker.

The box body comprises an upper shell, a lower shell for correspondingly coupling with the upper shell, and a sound chamber defined by the upper shell and the lower shell jointly. The sound chamber has a reflection duct extending inward from the upper shell and a sound cup extending inward from the lower shell. The sound cup is located to cover the outside of the reflection duct, and the sound cup and the reflection duct are spaced by a predetermined distance.

The loudspeaker has an outward expanded opening and the loudspeaker is mounted in the box body for generating the sounds.

The upper shell can be coupled with the lower shell easily by convex/concave engagement between the sound cup and the reflection duct. Accordingly, the reflection-type sound box has space-saving, small-noise, high-efficiency, and low-cost advantages.

### BRIEF DESCRIPTION OF THE DRAWINGS

These and other features, aspects and advantages of the present invention will become better understood with regard to the following description, appended claims, and accompanying drawings, wherein:

FIG. 1 is a cross-sectional diagram of the present invention;

FIG. 2 is an elevational diagram showing the reflection duct and the sound cup of the present invention;

FIG. 3 is a schematic diagram showing the usage status of the preferred embodiment of the present invention;

FIG. 4 is an elevational diagram showing other forms of the reflection duct and the sound cup of the present invention; and

FIG. 5 is an elevational diagram showing further forms of the reflection duct and the sound cup of the present invention.

### DETAILED DESCRIPTION OF THE PREFERRED EMBODIMENT

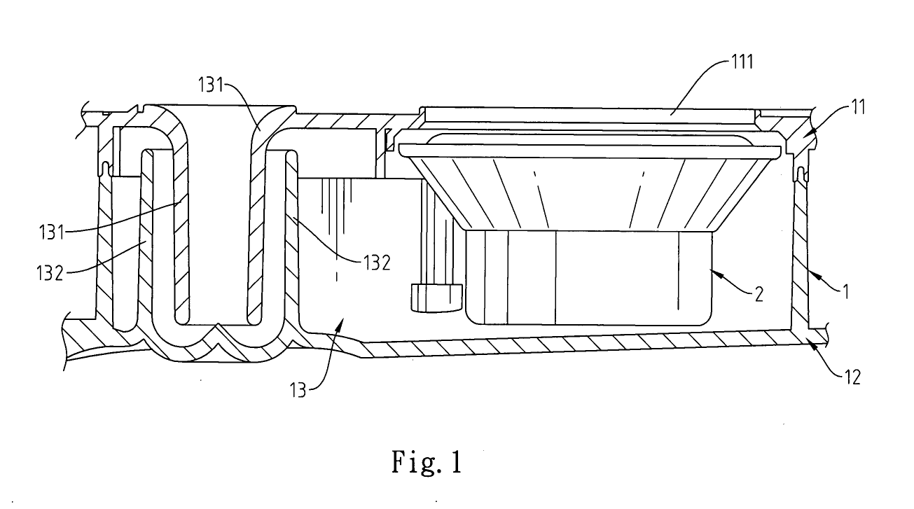

Referring to FIG. 1, a reflection-type sound box of the present invention generally comprises a box body 1 and a loudspeaker 2.

The box body 1 comprises an upper shell 11, a lower shell 12 for correspondingly coupling with the upper shell 11, and a sound chamber 13 defined by the upper shell 11 and the lower shell 12 jointly. The upper shell 11 has a through hole 111 penetrating thereof. The sound chamber 13 has a reflection duct 131 extending inward from the upper shell 11 and a sound cup 132 extending inward from the lower shell 12. The sound cup 132 is located to cover the outside of the reflection duct 131. The sound cup 132 and the reflection duct 131 are spaced by a predetermined distance.

The loudspeaker 2 has an outward expanded opening and the loudspeaker 2 is mounted in the through hole 111 of the box body 1 for generating the sounds.

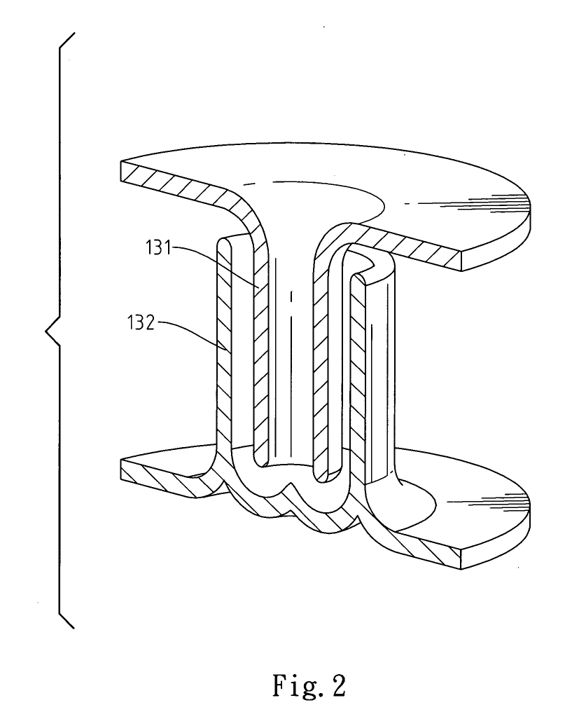

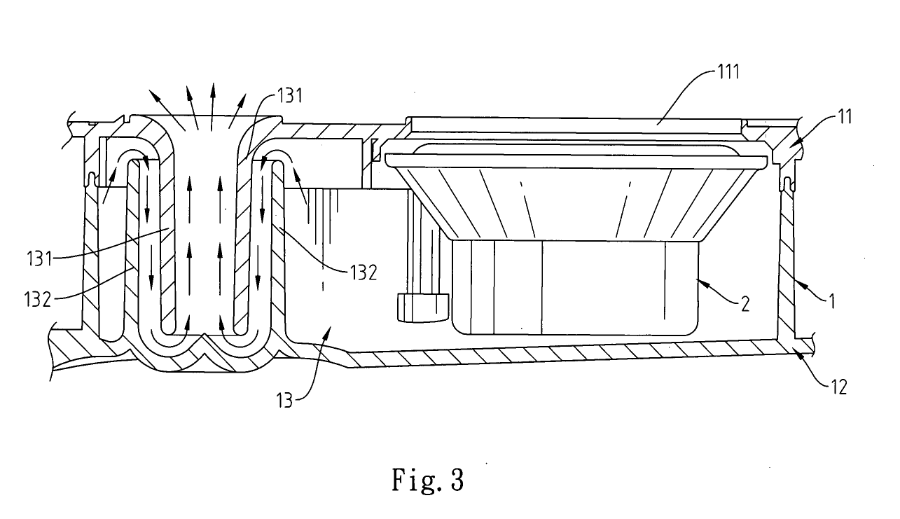

The usage status of the above-mentioned components is shown in FIG. 2 and FIG. 3. When the loudspeaker 2 generates the sounds, most of the sounds are sent out via the opening of the loudspeaker 2 while some of the sounds are remained in the box body 1, causing the generation of resonance effect in the box body 1. In addition, the sound cup 132 is impacted by the sound waves by compressing the air inside the box body 1 so as to generate the circular resonance in the sound cup 132 for raising the sound strength and obtaining a better audio frequency. Moreover, the audio frequency is guided into the reflection duct 131 via the sound cup 132, and then sent out radially via the opening on the other side of the reflection duct 131 for generating more powerful and strong sounds.

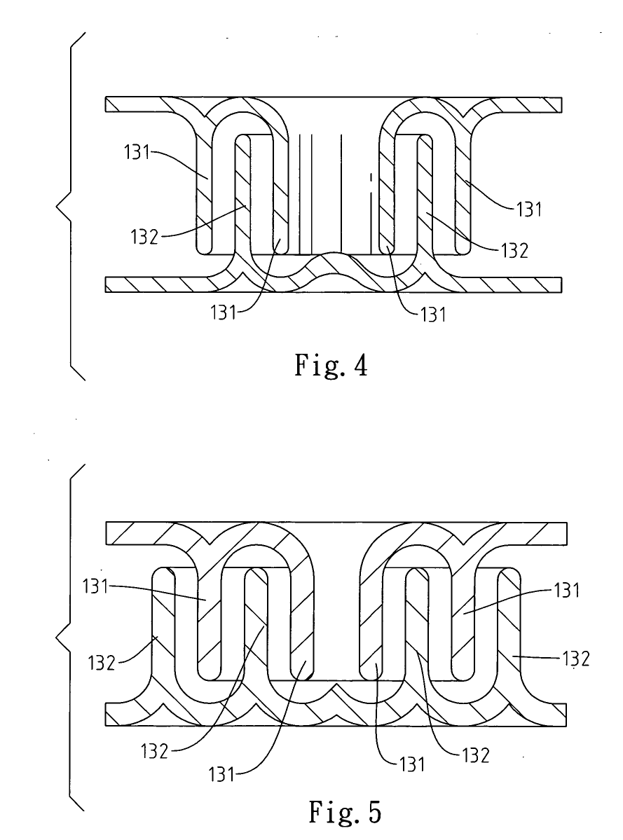

Furthermore, as shown in FIG. 2, in the above-mentioned preferred embodiment, the reflection duct 131 and the sound cup 132 of the sound chamber 13 are inverse U-shaped and W-shaped, respectively. In addition, the reflection duct 131 can be double U-shaped, as shown in FIG. 4. Besides, as shown in FIG. 5, the reflection duct 131 and the sound cup 132 can be double U-shaped or multiple U-shaped, respectively. Moreover, the multiple reflection duct 131 and the sound cup 132 better the whole efficiency and the tone color of the box body 1.

Furthermore, the upper shell 11 can be coupled with the lower shell 12 (shown in FIG. 1) by convex/concave engagement, not by lock-type connection. Accordingly, more pure sounds can be generated.

What the invention claimed is:

1. A reflection-type sound box comprising:
a loudspeaker; and
a box body comprising an upper shell, a lower shell for correspondingly coupling with said upper shell, and a sound chamber defined by said upper shell and said lower shell jointly, said sound chamber having a reflection duct extending inward from said upper shell and a sound cup extending inward from said lower shell, said sound cup being located to cover the outside of said reflection duct, and said sound cup and said reflection duct being spaced by a predetermined distance.

2. A reflection-type sound box of claim 1, wherein said upper shell is coupled with said lower shell by convex engagement.

3. A reflection-type sound box of claim 1, wherein said upper shell is coupled with said lower shell by concave engagement.
